(19) United States
(12) Patent Application Publication
(10) Pub. No.: US 2025/0051211 A1
(43) Pub. Date: Feb. 13, 2025

(54) TUBULAR COMPOSITE BODY OF QUARTZ GLASS AND METHOD FOR PRODUCING AND USING THE SAME

(71) Applicant: Heraeus Quarzglas GmbH & Co. KG, Hanau (DE)

(72) Inventors: Walter LEHMANN, Kleinostheim (DE); Klaus-Uwe BADEKE, Bitterfeld-Wolfen (DE); Martin HENGSTERMANN, Bitterfeld-Wolfen (DE); Steffen ZWARG, Bitterfeld-Wolfen (DE); Michael HÜNERMANN, Kleinostheim (DE)

(21) Appl. No.: 18/793,250

(22) Filed: Aug. 2, 2024

(30) Foreign Application Priority Data
Aug. 8, 2023 (EP) 23190227.1

(51) Int. Cl. C03B 19/14

(52) U.S. Cl. CPC C03B 19/1453; C03B 2201/04

(57) ABSTRACT

A method for producing a tubular quartz glass composite body in an outside deposition method comprising the following method steps: providing a substrate tube, rotating the substrate tube about a rotation axis, depositing SiO₂ particles on the outer lateral surface of the substrate tube to form a composite consisting of the substrate tube and an SiO₂ soot body, and sintering the composite by heating at a sintering temperature to form the tubular quartz glass composite body. A substrate tube is provided which consists at least partially of quartz glass of a first quartz glass quality, and that the soot body consist of quartz glass of a second quartz glass quality, wherein the first quartz glass quality has a material-specific viscosity at the sintering temperature that is higher than the material-specific viscosity of the second quartz glass quality.

### CROSS-REFERENCE TO RELATED APPLICATIONS

This application claims priority pursuant to 35 U.S.C. 119 (a) to European Application No. 23190227.1, filed Aug. 8, 2023, which application is incorporated herein by reference in its entirety.

### DESCRIPTION

Tubular composite body of quartz glass and method for producing and using the same

### TECHNICAL BACKGROUND

The present invention relates to a composite body of quartz glass—in particular, a tubular composite body of quartz glass with a length of at least 1,000 mm, a raw wall, and an inner diameter of at least 250 mm.

The invention also relates to the production of a tubular quartz glass composite body—in particular, a method for producing a tubular quartz glass composite body in an outside deposition method comprising the following method steps:
(a) Providing a substrate tube which has a continuous through-opening running coaxially with a substrate tube longitudinal axis, a substrate tube outer diameter, a substrate tube inner diameter, a substrate tube wall thickness, a substrate tube outer lateral surface, and a substrate tube inner lateral surface,
(b) Rotating the substrate tube about an axis of rotation running coaxially with or parallel to the substrate tube longitudinal axis,
(c) Depositing SiO₂ particles on the outer lateral surface of the substrate tube by means of at least one deposition burner to form a composite consisting of the substrate tube and an SiO₂ soot body,
(d) Sintering the composite by heating at a sintering temperature to form the tubular quartz glass composite body.

Components of quartz glass in the form of preforms, tubes, rods, flanges, plates, rings, reactors, crucibles, and the like are used in semiconductor production and for the manufacture of optical fibers. Such components are often produced from tubular semi-finished products of quartz glass by thermally shaping and/or mechanically processing them. As productivity increases, larger dimensions are increasingly being sought for such components, which is associated with greater wall thicknesses and internal diameters-particularly in the case of tubular semi-finished products.

For the production of tubular semi-finished products from synthetically produced silicon dioxide, CVD methods (chemical vapor deposition) are known, in which SiO₂ particles are deposited from the gas phase on a substrate. The CVD external deposition method known by the abbreviation, “OVD” (outside vapor deposition), is generally suitable for the production of large-volume semi-finished products. In this process, a silicon-containing starting material is converted into SiO₂ particles in a reaction zone by means of flame hydrolysis or pyrolysis, and these particles are deposited in layers on the outer jacket of a cylindrical substrate rotating around its longitudinal axis. The reaction zone is generated by means of a heat source, wherein the substrate longitudinal axis and the heating source move back and forth relative to one another. The substrate can be tubular and is also referred to here and in the following as a “substrate tube.” The substrate tube consists, for example, of quartz glass, SiC, SiSiC (reaction-bonded silicon carbide), Al₂O₃, or another ceramic material, or of graphite, and is held and rotated about its longitudinal axis by means of a lathe-like device, which is also referred to here as a “substrate tube holder.”

Depending upon the temperature during the deposition method, the layer of synthetic SiO₂ deposited on the substrate tube is still porous and is also referred to below as a “soot layer” or “soot body,” or it forms a dense layer of more or less transparent quartz glass. In the case of a porous soot layer, this body is sintered in a separate method step to form more or less transparent quartz glass (the sintering method is also referred to as “vitrification”). From the tubular quartz glass semi-finished product produced in this way, a component of synthetic quartz glass is obtained by mechanical, chemical, and/or thermal post-processing, such as a solid cylinder, a hollow cylinder, or parts of these components, which themselves can also serve as semi-finished products for the production of other components.

### BACKGROUND ART

U.S. Pat. No. 8,316,671B2 describes an OVD outside deposition method for producing a hollow cylinder of quartz glass. A substrate tube of quartz glass is provided, and a porous SiO₂ soot layer is deposited on its outer lateral surface. The composite consisting of substrate tube and SiO₂ soot layer is vitrified in such a way that the inside of the substrate tube remains below the deformation temperature. For this purpose, the inner bore of the substrate tube can be cooled by a gas or a liquid during the vitrification process. The inner wall of the tubular composite body of quartz glass produced in this way is formed by the substrate tube; it is smooth and no longer needs to be processed mechanically.

From US 2013/115391 A1, a method for producing hollow quartz glass cylinders with a large external diameter is known, wherein a porous soot body of silicon dioxide soot is deposited on a substrate using an OVD outside deposition method. After removing the substrate, the soot body is sintered to form a hollow cylinder. Rings are sawn from this, which consist of quartz glass with a low chlorine content and at the same time a low hydroxyl group content, and therefore have a high viscosity. The quartz glass rings are used as so-called “plasma etching rings” to hold semiconductor wafers in plasma etching systems.

To vitrify the soot body, it is held in a vertical orientation or in a horizontal orientation of its longitudinal axis in a sintering furnace. If the longitudinal axis is aligned vertically, the soot body can be vitrified standing on a platform. However, there is a risk that the soot body will deform and collapse due to its weight. A caterpillar-like structure made up of circumferential folds may form such that the dimensional accuracy requirements cannot be met; in particular, the specified minimum inner diameter may be exceeded.

The method known from EP 701 975 A2 avoids some of these disadvantages. The tubular soot body is introduced into a vitrification furnace and held therein in a vertical orientation by means of a holding device which comprises a holding rod which extends from above through the inner bore of the soot body and which is connected to a holding foot on which the soot body initially stands by its lower one end. The holding rod consists of carbon-fiber-reinforced graphite (CFC) and is tightly covered by a gas-permeable, thin-walled cladding tube of pure graphite. In a position above the upper end of the cladding tube, a graphite support ring is embedded in the inner bore of the soot body and protrudes inwards from the soot body wall into the inner bore of the soot body.

During vitrification, the soot body is moved zone-by-zone, starting with its upper end, through an annular heating element. The soot body gradually collapses onto the graphite cladding tube and also shrinks in length, whereby in a first sintering phase, it stands on the holding foot. The position of the graphite support ring embedded in the soot body is chosen so that it is supported on the graphite cladding tube in a second sintering phase due to the increasing longitudinal shrinkage such that the soot body is then held suspended at the upper end. This method is also referred to below as “suspended vitrification.” After vitrification, the cladding tube is removed, and the inner bore of the resulting quartz glass tube is finished by drilling, grinding, honing, or etching.

In order to reduce the graphite contact surfaces, in a modification of this method according to DE 103 03 290 B3, a sleeve of synthetic quartz glass is provided between the holding rod and the soot body to be vitrified. The production of this sleeve is associated with a large expenditure of time and money, and it is or becomes part of the quartz glass tube.

In the method known from DE 100 64 730 A, SiO₂ particles are deposited on an elongated substrate tube rotating about its longitudinal axis, which tube has a gradation of its outer diameter over its length. After removing the stepped substrate tube, a porous, hollow-cylindrical soot body is obtained, the inner bore of which has a complementary shape corresponding to the substrate tube's outside diameter profile, i.e., it has a step-shaped shoulder. The soot body obtained in this way is vitrified in a vertical orientation hanging in a furnace, wherein the narrowed region of the inner bore is arranged at the top, and a holding rod protruding from above into the inner bore reaches under the step-shaped shoulder. Reliably holding a heavy soot body requires a relatively wide shoulder of the inner bore.

### Technical Object

As quartz glass cylinders become increasingly larger, the weight of the soot bodies to be sintered, and the increasing temperature differences between inside and outside make the manufacturing method more difficult. With the procedures described above, reliable holding of heavy soot bodies during vitrification and reproducible production of tubes of quartz glass are problematic. In particular, scrap should be avoided at a late stage of the method, such as when vitrifying the soot body.

Similar problems also arise when vitrifying other bodies of porous SiO₂ that were not produced via the SiO₂ soot route—for example, with porous SiO₂ bodies that have been obtained via the well-known sol-gel route or by pressing methods.

The invention is therefore based upon the object of specifying a method for producing such large-volume, tubular composite bodies of quartz glass using an outside deposition method—in particular, using an OVD outside deposition method.

In particular, the invention is based upon the object of providing a process for the reproducible production of a tubular composite body of quartz glass with a large internal diameter according to the outside deposition method—in particular, with an internal diameter of more than 200 mm and with a wall thickness of more than 25 mm—which avoids the aforementioned disadvantages and in which, in particular, the risk of scrap is reduced.

In addition, the invention is based upon the object of providing a tubular quartz glass composite body which is characterized on the one hand by large dimensions, and in particular by an inner diameter of more than 200 mm, a wall thickness of more than 25 mm, and a length of at least 1,000 mm, and at the same time by high dimensional stability.

### GENERAL DESCRIPTION OF THE INVENTION

With regard to the method for producing the tubular composite body of quartz glass, this object is achieved, according to the invention, starting from a method of the type mentioned at the outset, in that a substrate tube is provided which consists at least partially of quartz glass of a first quartz glass quality, and that the soot body consists of quartz glass of a second quartz glass quality, wherein the first quartz glass quality has a material-specific viscosity at the sintering temperature that is higher than the material-specific viscosity of the second quartz glass quality.

The method includes a method step in which an SiO₂ porous soot body of synthetic silicon dioxide is produced using an outside deposition method—in particular, using an OVD outside deposition method—which is also referred to below as a “soot body.” The porous SiO₂ soot body can optionally be subjected to a dehydration treatment in inert gas, chlorine-containing gas, or under vacuum to reduce the hydroxyl group content of the quartz glass before it is sintered to form the more or less transparent quartz glass. The sintering (or vitrification) takes place, for example, under vacuum or in an atmosphere containing helium and/or hydrogen and/or nitrogen.

The substrate tube is designed to produce the SiO₂ soot body with a large inner diameter on its outer lateral surface using the outside deposition method. The substrate tube has, for example, a substrate tube length up to 4 m and is cylindrical, conical, or stepped over its entire length or over part of its length. The inner contour is constant over the length of the substrate tube, or it changes.

After the deposition method has been completed, the substrate tube remains in the composite consisting of the substrate tube and soot body and becomes a part of the tubular quartz glass composite body to be produced (hereafter also referred to as “quartz glass composite body,” or “composite body” for short). It consists of quartz glass and preferably has an inner diameter of at least 250 mm. Its wall thickness is preferably in a range of 4 mm to 10 mm and is therefore small in relation to its outer diameter.

The wall thickness is usually less than 20% of the substrate tube outside diameter. On the one hand, the substrate tube thus has a low weight, which reduces the dynamics of the rotational movement and facilitates handling and alignment, and, on the other, it has a low thermal mass, which keeps the heat dissipation and the formation of thermal stresses within the wall low.

On the other hand, the wall thickness of the substrate tube is large enough to support a large-volume SiO₂ soot body. Therefore, the wall thickness of the substrate tube is preferably at least 1% of the outer diameter of the substrate tube. The wall thickness “W_{S}” (in mm) can also depend upon the length of the substrate tube. It is advantageous if the wall thickness also increases with increasing length of the substrate tube. Therefore, W_{S} can alternatively be set as a function of the outer diameter D_{S} of the substrate tube (in mm), additionally taking into consideration the length of the substrate tube “L_{S}” (in mm), as follows: W_{S}<0.2*(L_{S}/2,000 mm)*D_{S}.

After completion of the outside deposition method and the optional dehydration treatment of the soot body, the soot body is sintered (vitrified) according to method step (d), viz., in the form of a composite consisting of a substrate tube and SiO₂ soot body, i.e., in connection with the substrate tube. The substrate tube used for this is characterized by high thermal stability so that, when the soot body is sintered, it becomes less soft than the soot body. The thermally more stable substrate tube gives the softening soot body a certain amount of support so that it achieves or maintains the desired cylindrical shape.

This is helped by the fact that both the substrate tube and the soot body consist of SiO₂, and therefore their thermal expansion coefficients do not differ, or do not differ significantly. The soot body sinters onto the substrate tube, so that a certain adhesion in the composite is ensured, and the soot body is prevented from detaching from the substrate tube during sintering.

The comparatively higher viscosity of the substrate tube is achieved, for example, in that it consists, over at least part of its length and/or at least over a thickness range of its wall, of a quartz glass which has a higher viscosity at the sintering temperature than the synthetic quartz glass of the soot body. In the simplest and preferred case, the substrate tube consists entirely of quartz glass of the first quartz glass quality, i.e., the higher viscosity quartz glass. In another, equally preferred embodiment, the quartz glass of the substrate tube consists of a higher viscosity quartz glass over only part of its length—for example, in the part of its length that is used as a holder in the sintering furnace when sintering the soot body.

The sintering temperature is typically in a range of 1,200° C. to 1,450° C. It has proven useful if, at a measuring temperature of 1,350° C., the decadal logarithm of the viscosity of the first quartz glass quality is at least 0.25 lg(dPa*s), preferably at least 0.4 lg(dPa·s), particularly preferably at least 0.6 lg(dPa·s) higher than that of the quartz glass of the second quartz glass quality. The viscosity differences are given here as the difference in the decadal logarithm lg(dPa·s) of the respective viscosity values. Differences in viscosity greater than 1 lg(dPa·s) at the measuring temperature are generally not necessary.

The viscosity of quartz glass can be changed by stiffening its glass network structure, and in particular by dopants. A stiffening of the glass network structure can be achieved through oxygen deficiency centers (also known as “ODC centers”). Nitrogen, titanium oxide, and aluminum oxide are dopants that are suitable for increasing the viscosity of quartz glass. In view of this, a preferred procedure provides that the quartz glass of the first quartz glass quality have an aluminum oxide content that is at least 5 ppm by weight, preferably at least 10 ppm by weight, higher than the aluminum oxide content in the quartz glass of the second quartz glass quality. Therefore, to increase the viscosity, aluminum oxide can be added to a quartz glass that is designed for components that are used at high temperatures and that are supposed to have a certain temperature stability. The viscosity of synthetically produced quartz glass can also be increased in this way.

Naturally occurring raw material for quartz glass often contains a certain amount of aluminum oxide. In view of this, the quartz glass of the first quartz glass quality is preferably melted from a naturally occurring raw material. The costs for producing the substrate tubes from natural quartz glass are comparatively low. For example, such substrate tubes can be produced economically using the known crucible drawing methods.

The quartz glass of the second quartz glass quality is, for example, highly pure, synthetically produced quartz glass without a significant amount of aluminum oxide or with a small amount of aluminum oxide of less than 1 ppm by weight, preferably less than 0.5 ppm by weight.

In contrast, the quartz glass of the first quartz glass quality preferably contains at least 5 ppm by weight, preferably at least 10 ppm by weight. However, an aluminum oxide content of more than 100 ppm by weight is generally not preferred.

The viscosity of quartz glass can also be changed by hydroxyl groups. Hydroxyl groups can lower the viscosity of quartz glass. In view of this, a preferred procedure provides that the quartz glass of the first quartz glass quality have a hydroxyl group content of less than 30 ppm by weight and preferably a hydroxyl group content of less than 20 ppm by weight.

Hydroxyl group contents of less than 30 ppm by weight can be achieved with a quartz glass quality produced from natural raw material—for example, by melting the raw material in an electrically heated furnace or using a hydrogen-free plasma. The hydroxyl group content of quartz glass produced synthetically via the SiO₂ soot route can be adjusted to a wide extent by drying the soot body before vitrification. By this drying treatment, low hydroxyl group contents in a range of a few ppm by weight can also be achieved in synthetically produced quartz glass, which are characterized by a comparatively low viscosity. If necessary, synthetic quartz glass that is low in hydroxyl groups is suitable as a substrate tube material, provided that the quartz glass of the soot body applied thereto has a comparatively low viscosity.

In a preferred method, a substrate tube is used which has a wall thickness in a range of 1.5 mm to 10 mm, preferably in a range of 4 to 8 mm.

The wall thickness is as large as necessary to ensure the desired thermal stability. On the other hand, the wall thickness is as small as possible, since the material of the substrate tube is generally removed during further processing of the quartz glass composite body.

The quartz glass composite body obtained after vitrification of this composite consisting of a substrate tube and SiO₂ soot layer has an inner wall region consisting of the first quality quartz glass, which originates from the former substrate tube. And it has an outer wall region consisting of second quality quartz glass which results from the former soot body. The thickness of the outer wall region scales with the wall thickness of the soot body and the soot density.

The soot density is typically in a range of 25 to 33% of the density of quartz glass. In view of this, the soot body obtained by the outside deposition method is, advantageously, essentially cylindrical, and it preferably has a wall thickness which, after sintering the composite body, results in a glass layer which has a layer thickness in a range of 25 mm to 100 mm, preferably in a range of 30 mm to 60 mm.

With regard to the tubular quartz glass composite body, the aforementioned technical object is achieved according to the invention, starting from a composite body of the type mentioned at the outset, in that the raw wall comprises an inner wall region and an outer wall region, wherein the inner wall region at least partially consists of quartz glass of a first quartz glass quality, and the outer wall region consists of quartz glass of a second quartz glass quality, wherein, at a measuring temperature of 1,350° C., the viscosity of the first quartz glass quality is higher than the viscosity of the second quartz glass quality.

The tubular quartz glass composite body can be produced according to the invention using the method explained above. The outer wall region of the quartz glass composite body is optionally formed from quartz glass which has been obtained by sintering a former SiO₂ soot body, and the inner wall region is formed by the quartz glass of the former substrate tube.

Since both the inner wall region as well as the outer wall region consist of quartz glass, their thermal expansion coefficients do not differ, or do not differ significantly. During the previous sintering, the soot body is sintered onto the substrate tube so that a certain adhesion in the composite body is guaranteed.

The comparatively higher viscosity of the inner wall region is achieved, for example, in that it consists, over at least part of its length and/or at least over a thickness range, of a quartz glass which has a higher viscosity at the measuring temperature of 1,350° C. than the synthetic quartz glass of the outer one wall region.

It has proven useful if, at a measuring temperature of 1,350° C., the decadal logarithm of the viscosity of the first quartz glass quality is at least 0.25 lg(dPa·s), preferably at least 0.4 lg(dPa·s), particularly preferably at least 0.6 lg(dPa·s) higher than that of the quartz glass of the second quartz glass quality. The viscosity differences are given here as the difference in the decadal logarithm lg(dPa·s) of the respective viscosity values. Differences in viscosity greater than 1 lg(dPa·s) at the measuring temperature are generally not necessary.

The inner wall area can have a holding element that, during the previous sintering process, has enabled suspended vitrification to form the quartz glass composite body. In a preferred embodiment, the quartz glass of the inner wall region consists of a higher viscosity quartz glass over only part of its length—for example, in the part of its length in which the holding element is located.

In the simplest and particularly preferred case, the inner wall region consists entirely of the quartz glass of the first quartz glass quality, i.e., the higher viscosity quartz glass.

The viscosity of quartz glass can be changed by stiffening its glass network structure, and in particular by dopants. A stiffening of the glass network structure can be achieved through oxygen deficiency centers (also known as “ODC centers”). Nitrogen, titanium oxide, and aluminum oxide are dopants that are suitable for increasing the viscosity of quartz glass.

In view of this, a preferred embodiment of the composite body provides that the quartz glass of the first quartz glass quality have an aluminum oxide content that is at least 5 ppm by weight, preferably at least 10 ppm by weight, higher than the aluminum oxide content in the quartz glass of the second quartz glass quality. Therefore, to increase the viscosity, aluminum oxide can be added to a quartz glass that is designed for components that are used at high temperatures and that are supposed to have a certain temperature stability. The viscosity of synthetically produced quartz glass can also be increased in this way.

Naturally occurring raw material for quartz glass often contains a certain amount of aluminum oxide. In view of this, the quartz glass of the first quartz glass quality is preferably melted from a naturally occurring raw material. The cost of producing natural quartz glass is comparatively low.

The quartz glass of the second quartz glass quality is, for example, highly pure, synthetically produced quartz glass without a significant amount of aluminum oxide or with a small amount of aluminum oxide of less than 1 ppm by weight, preferably less than 0.5 ppm by weight.

In contrast, the quartz glass of the first quartz glass quality preferably contains at least 5 ppm by weight, preferably at least 10 ppm by weight. However, an aluminum oxide content of more than 100 ppm by weight is generally not preferred.

The viscosity of quartz glass can also be changed by hydroxyl groups. Hydroxyl groups can lower the viscosity of quartz glass. In view of this, a preferred embodiment of the composite body provides that the quartz glass of the first quartz glass quality have a hydroxyl group content of less than 30 ppm by weight and preferably a hydroxyl group content of less than 20 ppm by weight.

Hydroxyl group contents of less than 30 ppm by weight can be achieved with a quartz glass quality produced from natural raw material—for example, by melting the raw material in an electrically heated furnace or using a hydrogen-free plasma. The hydroxyl group content of quartz glass produced synthetically via the SiO₂ soot route can be adjusted to a wide extent by drying the soot body before vitrification. By this drying treatment, low hydroxyl group contents in a range of a few ppm by weight can also be achieved in synthetically produced quartz glass, which are characterized by a comparatively low viscosity. If necessary, synthetic quartz glass that is low in hydroxyl groups is suitable as a substrate tube material, provided that the quartz glass of the soot body applied thereto has a comparatively low viscosity.

In a preferred embodiment of the composite body, the inner wall region consisting of the first quality quartz glass has a wall thickness in a range of 1.5 mm to 10 mm, preferably in a range of 4 to 8 mm.

The wall thickness is as large as necessary to ensure the desired thermal stability. On the other hand, the wall thickness is as small as possible, since the first quality quartz glass is usually removed during further processing of the composite body.

In a preferred embodiment of the composite body, the outer wall region has a wall thickness in a range of 25 mm to 100 mm, preferably in a range of 30 mm to 60 mm.

A hollow quartz glass cylinder is produced from the quartz glass composite body by removing the inner wall region—for example, by drilling, milling, or etching. The hollow quartz glass cylinder obtained in this way is used to produce etching rings for single-wafer plasma etching chambers or pressure vessels for use in chemical method engineering.

The etching rings or pressure vessels have a specified target inside diameter. For the production of the etching rings or pressure vessels, a composite body is preferably used with an outer wall region with an inner diameter that is at least 1 mm smaller than the target inner diameter. The target inner diameter is adjusted by removing the entire inner wall region and an excess on the outer wall region, wherein the excess is 1 mm or more.

### Definitions and Measurement Methods

Individual terms of the above description are further defined below. The definitions are part of the description of the invention. For terms and measuring methods that are not specifically defined in the description, the interpretation according to the International Telecommunication Union (ITU) is relevant. In the event of an inconsistency between one of the following definitions and the rest of the description, the statements made in the description take precedence.

### Tubular Composite Body of Quartz Glass

The result of the deposition method is a tubular composite consisting of a substrate tube made of quartz glass and an SiO₂ soot body. The substrate tube borders the internal bore of the composite. By sintering (vitrifying) the soot body, a tubular composite body of quartz glass is obtained. By subsequently removing the substrate tube from the quartz glass composite body, a hollow quartz glass cylinder is obtained. The substrate tube is removed, for example, by drilling out. Through mechanical, thermal, or chemical further processing, components of quartz glass are created from the hollow quartz glass cylinder. Further mechanical processing includes drilling, sawing, cutting, milling, grinding, and polishing the inner and outer contours. Thermal further processing includes thermal drying, sintering, vitrification, melting, forming, and tempering. Further chemical processing includes doping and etching. The component of quartz glass is a ready-to-use quartz glass product or a semi-finished product—for example, a quartz glass hollow cylinder for producing a pressure vessel, or a quartz glass ring for producing a holding ring for wafers.

### Quartz Glass/Synthetic Quartz Glass

Quartz glass is understood here to mean glass with an SiO₂ content of at least 87 wt %. It is undoped (SiO₂ content=100%) or contains dopants such as fluorine, chlorine, nitrogen, carbon, or oxides of boron, germanium, rare earth metals, aluminum, or titanium.

Quartz glass is, for example, a melted product from naturally occurring SiO₂ raw material (natural quartz glass), or it is synthetically produced (synthetic quartz glass) or consists of mixtures of these quartz glass types.

### Sintering/Vitrification

“Sintering” or “vitrification” here denotes a method step in which a soot body of porous silicon dioxide is treated in a furnace at high temperature. Sintering/vitrification takes place in inert gas, an atmosphere containing hydrogen and/or helium, or under vacuum.

### Vacuum

The vitrification of the composite body can be carried out under a “vacuum.” The negative pressure is expressed as the absolute gas pressure. Vacuum means an absolute gas pressure of less than 50 mbar.

### Substrate Tube Outer Diameter/Substrate Tube Inner Diameter

The substrate tube cross-section has a circular outer contour or an outer contour that deviates from the round shape. If the outer contour deviates from the round shape, the local “outer diameter value” is given by the diameter of the (smallest) circumference.

The substrate tube cross-section has a circular inner contour or an inner contour deviating from the round shape. If the inner contour deviates from the round shape, the local “inner diameter value” is given by the diameter of the (largest) inscribed circle.

In the longitudinal section of the substrate tube, the local values for the outside diameter are constant or not constant over the entire length of the substrate tube. In the case of constant outer diameter values, the substrate tube has a cylindrical shape, seen from the outside. The non-constant outer diameter values can vary over the total length or over a partial length. The outer contour can change continuously or gradually, for example. In this case, the outer diameter results from the local outer diameter values averaged over the total length.

In the longitudinal section of the substrate tube, the local values for the outside diameter are constant or not constant over the entire length of the substrate tube. In the case of constant inner diameter values, the through-opening of the substrate tube is cylindrical. The non-constant inner diameter values can vary over the total length or over a partial length. The inner contour can change continuously or gradually, for example. In this case, the inner diameter results from the local inner diameter values averaged over the total length.

### Viscosity

The “viscosity” of the quartz glass is measured using a beam-bending viscometer. Beam-bending viscometry covers a viscosity range of 10⁸ to 10¹⁵ dPa·s (in logarithmic units: from 8 Ig (dPa·s) to 15 Ig dPa·s. The measuring setup includes a heatable, three-point bending device with a measuring bar of the quartz glass to be measured (bar/strip: 50 mm long, 3 mm high, 5 mm wide). The measured variable is the deflection speed at the respective temperature.

Instead of using exponential notation, viscosity values are often also indicated using the decadal logarithm in the form, Ig (dPa·s).

### Softening Temperature

Glasses cannot be assigned a specific softening temperature, but, rather, a softening temperature range. In order to determine a temperature value, reference is made here to the determination according to DIN ISO 7884 (1998), according to which the softening temperature is defined as the temperature at which the glass has a viscosity of 107.6 dPa·s (7.6 lg(dPa·s)). Temperature values in a range of 1,600° C. to 1,730° C. are mentioned in the literature for the softening temperature of undoped quartz glass.

### EXEMPLARY EMBODIMENT

The invention is explained in more detail below with reference to exemplary embodiments and a patent drawing. In detail, in a schematic representation,

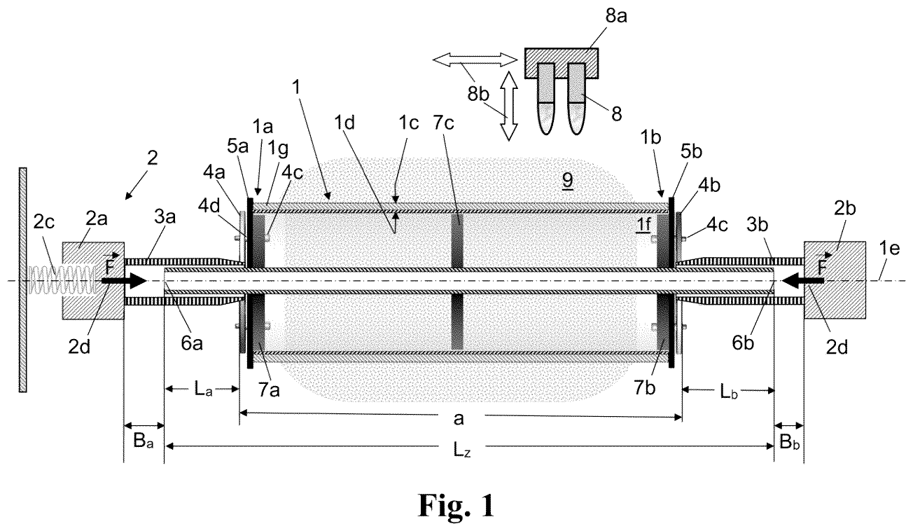

FIG. 1 shows a device for producing a composite body consisting of a substrate tube and a soot body in a first embodiment of a substrate tube holder in a longitudinal section;

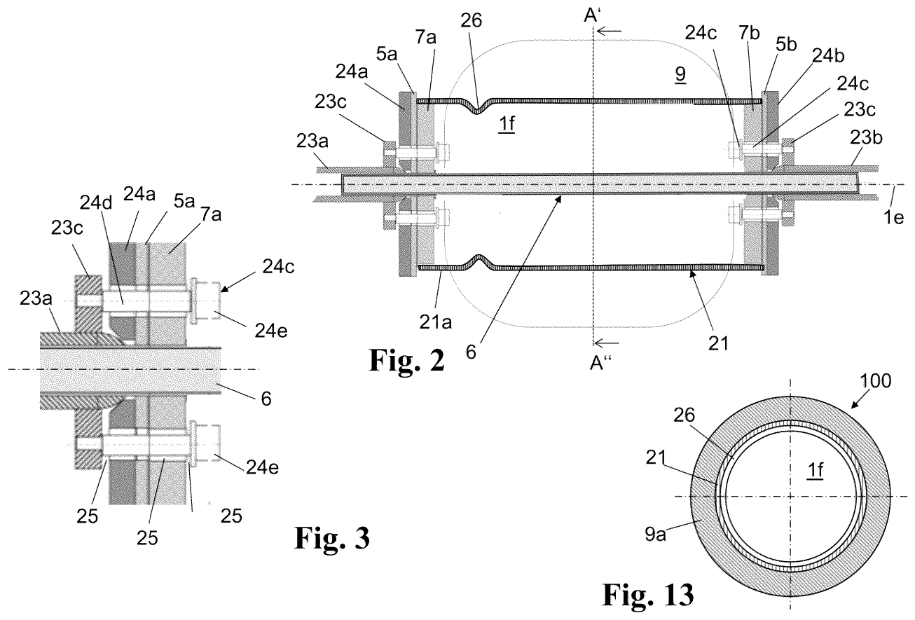

FIG. 2 shows a device for producing a composite body consisting of a substrate tube and a soot body in a second embodiment of a substrate tube holder in a longitudinal section, partly as a cutout;

FIG. 3 shows an enlarged view of a section of the substrate tube holder of FIG. 2;

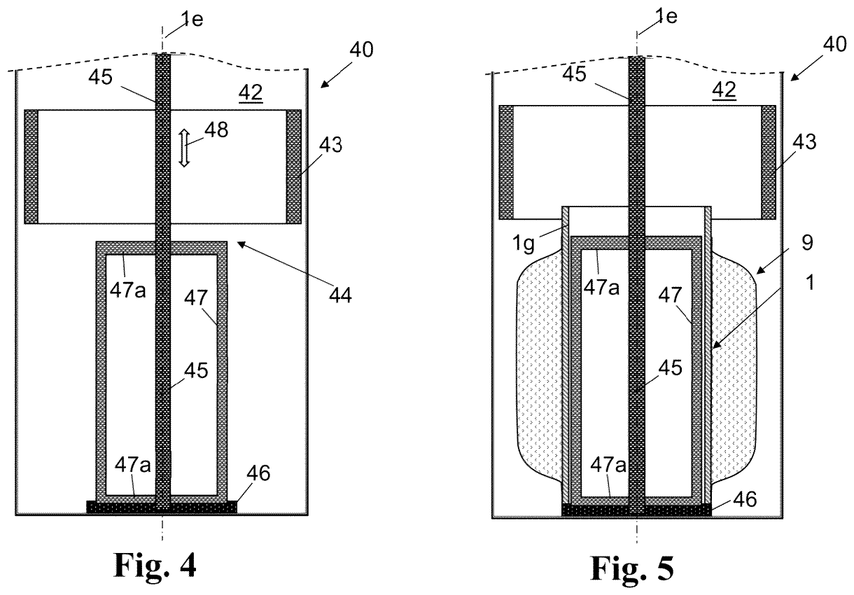

FIG. 4 shows components of a zone sintering furnace as used for vitrifying a composite body;

FIG. 5 shows the vitrification of a standing composite body using the zone sintering furnace;

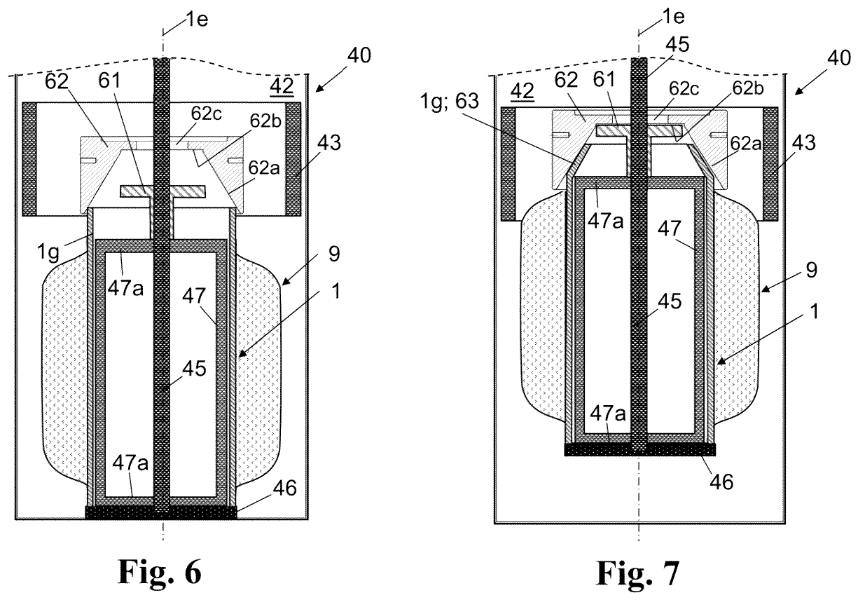

FIG. 6 shows a method step for producing a first embodiment of a holding edge on the substrate tube;

FIG. 7 shows a further method step for producing the holding edge on the substrate tube;

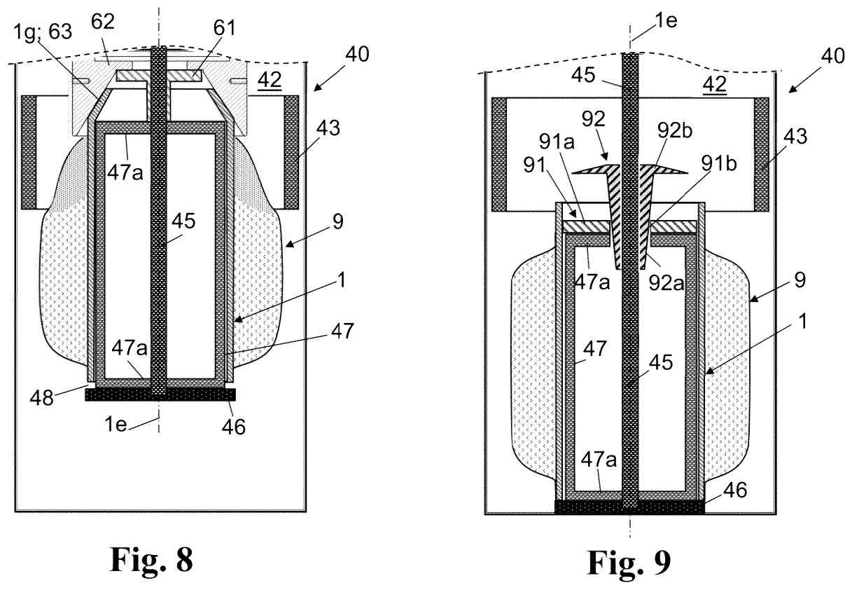

FIG. 8 shows the vitrification of a partially suspended composite body using the first embodiment of the holding edge on the substrate tube in the zone sintering furnace;

FIG. 9 shows a method step for producing a second embodiment of a holding edge on the substrate tube;

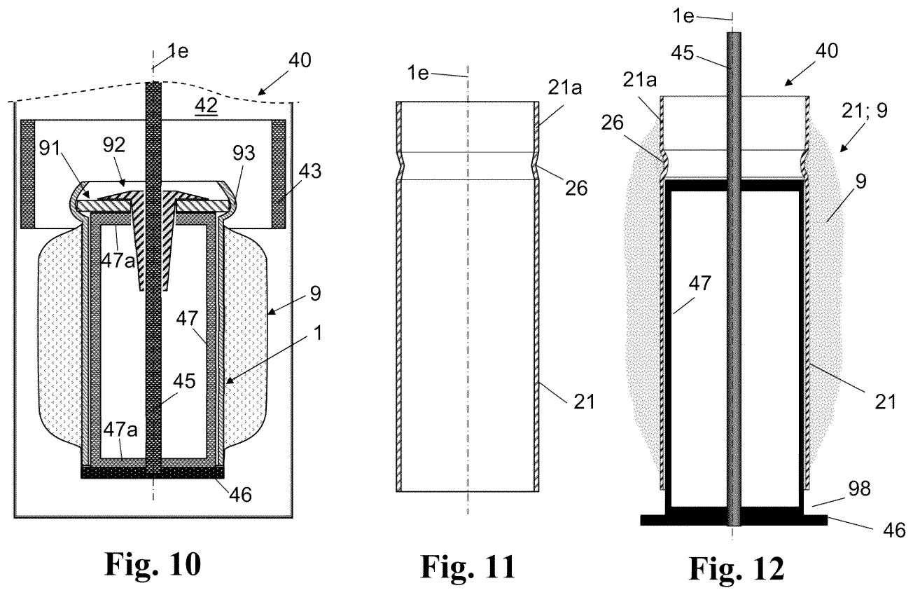

FIG. 10 shows a further method step for producing the holding edge on the substrate tube;

FIG. 11 shows an embodiment of a substrate tube with a holding edge, produced before the outside deposition method, in the form of a taper of its inner diameter;

FIG. 12 shows the substrate tube of FIG. 11 after completion of the outside deposition method when vitrifying the composite body in the zone sintering furnace of FIG. 4; and,

FIG. 13 shows an exemplary embodiment of a tubular quartz glass composite body according to the invention in a longitudinal section.

In the exemplary embodiments explained below, different substrate tubes are used, some of the properties of which are summarized in Table 1.

TABLE 1
Substrate tubes

| | Viscosity | OH | | | | |
|---|---|---|---|---|---|---|
| | [lg(dPa · s) | content | Outside | Inner | | |
| | at | [ppm by | diameter | diameter | Length | |
| Material | 1,350° C.] | weight] | [mm] | [mm] | [mm] | Shape |
| Natural | 11.28 | 20-30 | 280 | 270 | 2,000 | Cylinder |
| quartz | | | | | | |
| glass | | | | | | |
| (electrically | | | | | | |
| melted) | | | | | | |
| Natural | 11.28 | 20-30 | 280 | 270 | 1,500 | Cylinder |
| quartz | | | | | | with |
| glass | | | | | | constriction |
| (electrically | | | | | | |
| melted) | | | | | | |
| Synthetic | 10.77 | 200 | 280 | 270 | 1,500 | Cylinder |
| quartz | | | | | | with |
| glass | | | | | | constriction |
| (thermally | | | | | | |
| dried) | | | | | | |
| Synthetic | 10.64 | <0.2 | 280 | 270 | 1,500 | Cylinder |
| quartz | | | | | | with |
| glass | | | | | | constriction |
| (dried with | | | | | | |
| chlorine) | | | | | | |

“Natural quartz glass” is melted from naturally occurring SiO₂ raw material-preferably in an electrically heated melting furnace. A particularly cost-effective production of the substrate tube consisting of natural quartz glass is carried out using a vertical crucible drawing method. This quartz glass typically contains aluminum oxide in a concentration in a range of 6 ppm by weight and 18 ppm by weight and hydroxyl groups in a concentration of less than 50 ppm by weight. “Synthetic quartz glass” is obtained for example by flame hydrolysis or oxidation of synthetically produced silicon compounds, by polycondensation of organic silicon compounds according to what is referred to as the sol-gel method, or by hydrolysis and precipitation of inorganic silicon compounds in a liquid. The viscosity of synthetic quartz glass depends upon its composition, which can vary within a wide range. In general, however, it can be said that synthetic quartz glass typically has a significantly lower viscosity than natural quartz glass.

The device shown schematically in FIG. 1 is used to produce a large-volume composite consisting of a substrate tube 1 and an SiO₂ soot body 9. It includes a glass lathe 2 for holding and rotating the substrate tube 1 according to number 1 from Table 1. The substrate tube 1 has a left end face 1a, a right end face 1b, an outer lateral surface 1c, an inner lateral surface 1d, a horizontally-oriented longitudinal axis 1e, and a cylindrical through-hole 1f. Adjacent to the front end 1a, there is a free substrate tube section 1g on which a reduced deposition of SiO₂ soot particles takes place during the soot deposition process. The free substrate tube section 1g can be formed into a holding edge during vitrification, which will be explained in more detail below with reference to FIGS. 4 and 6 through 10.

The glass lathe 2 is indicated by two, oppositely-situated chucks 2a, 2b, of which the chuck 2a is spring-loaded, as indicated by the compression spring 2c. The compression spring 2c generates a pressure force F that presses the two chucks 2a, 2b against each other, as indicated by the directional arrows 2d.

A hollow spindle 3a, 3b made of stainless steel is clamped in each of the chucks 2a, 2b at their proximal ends. In the ideal case, the axes of rotation of the hollow spindles 3a, 3b run coaxially with the substrate tube longitudinal axis 1e. The hollow spindles 3a, 3b have an outer diameter of 90 mm and an inner diameter of 82 mm.

The distal ends of the hollow spindles 3a, 3b are pivotably connected to an annular pressure plate 4a, 4b made of stainless steel. For this purpose, the distal ends of the hollow spindles 3a, 3b taper conically and, as a result of the force of the spring 2c, press against the corresponding pressure plate 4a, 4b. Here, the conical end protrudes into a center bore of the respective annular pressure plate 4a, 4b and abuts the inner edge of the center bore.

The pressure plates 4a, 4b each abut buffer disks 5a, 5b made of graphite, which in turn abut the substrate tube end faces 1a and 1b, respectively. The buffer disks 5a, 5b have a central bore whose diameter corresponds to that of the pressure plates and which run coaxially with these. The pressure plates 4a, 4b have an outer diameter that is 10 mm smaller than the outer diameter of the substrate tube 1. The buffer disks 5a, 5b have an outer diameter that extends beyond the outer diameter of the substrate tube 1 by 40 mm.

A tubular centering support 6 of SiSiC with a total length L_{Z} and an outer diameter of 80 mm extends through the substrate tube through-hole 1f and through the center bores of pressure plates 4a, 4b and buffer disks 5a, 5b. One end 6a of the centering support 6 projects into the hollow spindle 3a over a length Lₐ of 500 mm and ends inside it, leaving a variable movement clearance Bₐ of approximately 6 mm. The other end 6b protrudes into the hollow spindle 3b over a length L_{b} of 600 mm and ends inside it, leaving a variable movement clearance B_{b} also of about 6 mm. The entire movement clearance B_{z}=Bₐ+B_{b} for the centering support 6 within the hollow spindles 3a, 3b is thus 12 mm. The outer diameter of the centering support 6 is constant over its length and is adapted with a clearance fit to the inner diameter of the hollow spindles 3a, 3b and telescopically displaceable therein.

Three centering rings 7a, 7b, 7c made of graphite are placed on the centering support 6. The centering ring 7a is located in the area of the left substrate tube end face 1a, the centering ring 7b is located in the area of the right substrate tube end face 1b, and the centering ring 7c is located approximately in the middle of the substrate tube through-hole 1f. All centering rings 7a, 7b, 7c have an outer diameter that is matched to the inner diameter of the substrate tube with a clearance fit, and they have an inner diameter that is matched to the outer diameter of the centering support with a clearance fit.

The end centering ring 7a, the buffer disk 5a, and the pressure disk 4a are loosely connected to each other by means of screws 4c. The screws 4c have a thread which adjoins a cylinder portion 4d. The screw thread engages in each case in an internal thread in the pressure disk 4a, so that the cylinder portion 4d lies firmly against the pressure disk 4a in the tightened state. The length of the cylinder portion 4d is greater than the total thickness of the component stack of centering ring 7a and buffer disk 5a, so that the heads of the screws 4c do not rest against the centering ring 7a, but a gap remains between the centering ring 7a and the screw heads. Furthermore, the through-holes for the passage of the cylindrical portion 4d in the buffer disk 5a and in the centering ring 7a are greater than the diameter of the cylinder portion 4d, so that the screws 4c can also be slightly inclined in the through-holes. This loose connection is therefore suitable both for allowing thermally-induced changes in length between components of the substrate tube holder and for compensating for deviations in the target dimensions, positioning, and alignment of the components. In addition, the screws 4c provide a certain torsional strength between the buffer disk 5a and the pressure disk 4a during the rotational movement of the substrate tube 1, and, in this respect, serve as driving elements for this rotational movement. The same applies to the connection of the centering ring 7b, the buffer disk 5b, and the pressure disk 4b. A gap is provided between the centering ring 7a, 7b and the buffer disk 5a, 5b for the purpose of thermal decoupling (not visible in the figure).

Several deposition burners 8 for generating SiO₂ particles are mounted on a common slide 8a, by means of which they can be moved reversibly and transversely along the outer lateral surface 1c of the substrate tube 1 or along a forming SiO₂ soot body 9, and can be displaced perpendicularly thereto, as indicated by the directional arrows 8b.

When the same reference numerals are used in FIG. 2 and in FIG. 3 as in FIG. 1, these designate identical or equivalent components or components of the device.

The device shown schematically in FIG. 2 differs from that of FIG. 1 essentially in the type and characteristics of the substrate tube holder and the substrate tube 21. If the same reference numbers are used as in FIG. 1, they designate identical or equivalent components or components of the device explained with reference to FIG. 1.

The substrate tube 21 corresponds to number 2 from Table 1. In an end region 21a, it has a circumferential constriction 26 of its inner diameter. The constriction 26 is created before the start of the outside deposition method—for example, by locally softening the substrate tube 21 after it has been clamped in the glass lathe 2. The constriction 26 is located at a distance of approximately 80 mm in front of the substrate tube end face. The inner diameter is 270 mm, except in the area of constriction 26, where it is 250 mm.

The hollow spindles 23a, 23b, which are each clamped in clamping chucks with their proximal end, are made of stainless steel. In the ideal case, the axes of rotation of the hollow spindles 23a, 23b run coaxially with the substrate tube longitudinal axis 1e. The hollow spindles 23a, 23b have an outer diameter of 100 mm. A circumferential extension arm 2c is welded in each case in the region of the distal ends of the hollow spindles 23a, 23b.

The pivoting connection between the hollow spindles 23a, 23b and the corresponding pressure plates 24a, 24 is designed here as a floating bearing and preferably comprises a cardan ball cone seat. Here, the distal ends of the hollow spindles 23a, 23b each form a convexly-curved seat which has a spherical or radius section on which the pressure plate 24a or the pressure plate 24b is movably mounted by having a concavely-curved spherical or radius section cooperating with the convexly-curved seat.

FIG. 3 shows an enlarged view of the pivoting connection between the hollow spindles 23a, 23b and the respective pressure plates 24a, 24b. The end centering ring 7a, the buffer washer 5a, and the pressure disk 24a form a stack of components that are loosely connected to each other by means of threaded screws 24c, each of which engages in a thread in the extension arm 23c. The cylindrical portion 24d has a length which is greater than the total thickness of the component stack consisting of centering ring 7a, buffer disk 5a, and pressure disk 24a. In addition, the width of the bore for receiving the threaded screws 24c in the component stack is significantly larger than the diameter of the cylinder portion 24d. This leads to several gaps 25 remaining both between the screw head 24e and the centering ring 7a and between the pressure plate 24 and the extension arm 23c, even with a fixedly-tightened threaded screw 24c, and along the cylinder portion 24d. The gaps 25 ensure that the connection between the hollow spindles 23a, 23b and the corresponding pressure plates 24a, 24b remains pivotable. At the same time, the screws 24c serve as driver elements for the rotational movement of the substrate tube 1.

Examples of producing a quartz glass composite body are explained below with reference to FIGS. 1 and 4 through 10.

### Soot Deposition Process

Oxygen and hydrogen are supplied to the deposition burners 8 as burner gases, and a gas stream containing SiCl₄ or another silicon-containing starting material is supplied as feed material for the formation of SiO₂ particles. These components are converted into SiO₂ particles in the relevant burner flame, and these SiO₂ particles are deposited on the substrate tube 1 rotating around the longitudinal axis 1e, forming the soot body 9 from porous SiO₂ soot.

To rotate the substrate tube 1, the glass lathe 2 transmits a torque to the hollow spindles 2a, 2b. At the same time, a pressure force F acting in the axial direction is generated by means of the compression spring 2c, which pressure force presses the two hollow spindles 3a, 3b against one another and which, depending upon the deflection of the spring from the spring rest length, is in a range between 0.5 kN and 10 kN. The initially set pressure force is 1 kN and is applied to the pressure plates 4a, 4b, the buffer disks 5a, 5b, and thus also to the substrate tube end faces 1a, 1b. This pressure force F creates a frictional connection between the buffer disks 5a, 5b, which is sufficient to hold the inherent weight of the substrate tube 1 and the weight of the soot body 9. The centering rings 7a, 7b, 7c are used only to prevent the substrate tube 1 from slipping or bending unexpectedly. A certain amount of axial guidance is provided by the interaction of hollow spindles 3a, 3b and centering support 6, which, due to the mechanical play present, compensates for any radial offsets and angular differences between the axes of rotation of the hollow spindles 3a, 3b, and avoids mechanical stresses.

The deposition method is terminated as soon as the soot body 9 has reached a predetermined outer diameter, which, as a function of the density of the soot layer, leads to the predetermined outer diameter of the hollow-cylindrical quartz glass compound body, plus an allowance of at least 1 mm. Given a soot density of approximately 30% (with reference to the density of quartz glass) and a target external diameter of the quartz glass composite body of 362 mm, the soot body external diameter is, for example, approximately 520 mm.

After the deposition method, the soot body 9 has a substantially barrel-like shape and extends to just before the ends of the substrate tube 1 on both sides. The substrate tube section 1g protruding from the soot body 9 and only slightly covered with SiO₂ soot has a length of approximately 100 mm.

### Drying and Vitrification Process

The substrate tube 1 remains in the soot body 9. The composite (1; 9) consisting of the substrate tube 1 and soot body 9 is subjected to a dehydration treatment in a drying furnace in an inert gas atmosphere, a halogen-containing atmosphere, or under vacuum. The soot body 9 is dried here thermally by heating to a temperature of around 1,100° C. in a nitrogen atmosphere. By vitrifying the dried SiO₂ soot body obtained afterwards under vacuum, a synthetic quartz glass with the following properties is obtained:
Hydroxyl group content: about 200 ppm by weight,
Chlorine content: <0.2 ppm by weight,
Viscosity at 1,350° C.: 10.77 Ig (dPa·s).

The subsequent vitrification of the soot body 9 takes place in a zone sintering furnace with a vertically-oriented substrate tube longitudinal axis 1e under vacuum or in an atmosphere of gases that diffuse quickly in quartz glass, such as helium and hydrogen, and therefore do not cause bubbles. FIG. 4 schematically shows a section of such a zone sintering furnace 40. The furnace chamber 41 encloses a furnace interior 42 in which an annular heating element 43 and a holding device 44 are located. This includes a support rod 45 of fiber-reinforced carbon, the lower end of which is connected to a platform 46 of graphite. The upper end of the support rod 45 is held by a movable gripper (not shown in the figure) and can be moved up and down by means of this. The support rod 45 extends through the ring opening of the heating element 43 and through a cladding tube 47 of graphite which stands on the platform 46.

Apart from the passages for the support rod 45, the cladding tube end faces are closed. In comparison to a cladding tube that is open on both sides, the largely closed top and bottom 47a give the cladding tube 47 greater dimensional rigidity against external pressure.

During vitrification, the substrate tube 1 remains in the soot body 9. The holding device 44 serves to hold the composite (1; 9) consisting of the substrate tube 1 and soot body 9, the weight of which over the platform 46 is held by the support rod 45. As shown schematically in FIG. 5, the substrate tube 1 surrounds the cladding tube 47. Its outer diameter is adapted to the inner diameter of the substrate tube 1 so that the annular gap remaining during sintering is as small as possible, taking into account the higher thermal expansion coefficient of the graphite cladding tube 47 compared to the quartz glass substrate tube, and is, for example, in a range of 1 mm to 10 mm, preferably less than 5 mm.

During vitrification, the heating element 43 is heated to a temperature of approximately 1,400° C., and the support rod 45 is continuously pulled upwards so that the soot body 9 is vitrified from top to bottom. The composite (1; 9) shrinks onto the cladding tube 47 so that its outer diameter defines a lower limit for the inner diameter of the vitrified, tubular quartz glass composite body. The substrate tube 1 consists of natural quartz glass, which has a higher viscosity at the sintering temperature than the synthetic quartz glass of the soot body 9. At a measuring temperature of 1,350° C., according to Table 1, the difference in viscosity corresponding to the difference in the decadal logarithms of the respective viscosity values is approximately 0.51 lg(dPa*s) [11.28 lg(dPa*s)−10.77 lg(dPa*s)].

The substrate tube 1 is therefore comparatively thermally stable and does not deform, or deforms slightly. This causes the soot body 9 to be stabilized during vitrification. In particular, the risk is counteracted of the soot body 9 collapsing during vitrification and circumferential folds forming, or the inside diameter widening, which leads to scrap.

After cooling, a tubular composite body is obtained from the substrate tube 1 and a glass layer with a thickness of approximately 41 mm, which has been obtained by vitrifying the soot body 9. Despite the fact that the synthetic quartz glass is shrunk onto the inner graphite cladding tube 47, it can be easily removed after vitrification, because graphite has a significantly higher coefficient of thermal expansion than quartz glass, and it contracts more strongly while cooling.

The quartz glass of the substrate tube 1 can then be removed by mechanical processing—for example, by drilling. After grinding and smoothing the outer wall, a hollow quartz glass cylinder with an outer diameter of 360 mm and an inner diameter of 290 mm is obtained.

### Comparative Example

As explained above, the substrate tube 1 contributes to the stabilization of the shape of the soot body 9 during vitrification due to its comparatively high viscosity.

In order to examine the effect of the substrate tube 1 on the stabilization of the shape of the soot body 9, in a first comparative test, the substrate tube was removed before vitrification, and only the soot body 9 was vitrified from top to bottom in the zone sintering furnace 40. The soot body 9 collapsed under its own weight, and the vitrified area detached from the cladding tube 47, which leads to a local expansion of the inner diameter. The quartz glass tube produced in this way was unusable.

In another comparative test, a substrate tube of synthetic quartz glass with the same dimensions as the substrate tube 1 was used, as specified in Table 1. The viscosity of this quartz glass is lower than the viscosity of the quartz glass obtained by vitrifying the soot body 9. It was revealed that, when this composite body is used, the cladding tube lends better adhesion to the vitrified soot body 9, so that there was no detachment of the vitrified material over a large area. However, the continuously increasing weight of the vitrified upper region of the composite body led to compression towards the end of the process, so that the quartz glass tube produced in this way was ultimately unusable.

In a further comparative test, a substrate tube of synthetic quartz glass with the same dimensions as the substrate tube 1 was used, as specified in Table 1. The viscosity of this quartz glass corresponds to the viscosity of the quartz glass that is obtained by vitrifying the soot body 9. However, it can also be seen here that, when the composite (1; 9) is sintered, compression occurs towards the end of the process, so that the quartz glass tube produced in this way was ultimately unusable.

### Suspended Vitrification

In order to counteract the effect of compression from intrinsic weight, a vitrification method is often used in which the composite (1; 9) does not stand permanently on the platform 46 during vitrification, but is kept hanging at least temporarily. This procedure, which is known for example from EP 0 701 975 B1, is referred to here for short as “suspended vitrification.”

This ensures that the composite (1; 9) is either held suspended in the vitrification furnace from the start, or that the holder of the composite (1; 9) can change from a standing holder at the start of vitrification to a hanging holder during the vitrification method as soon as the inevitable axial sintering shrinkage becomes noticeable. To realize the hanging holder, measures can be taken on the substrate tube even before the outside deposition method is carried out. This can be done, for example, by shaping a substrate tube or through the shaping process in the production of the substrate tube, such as by creating a constriction of the substrate tube inner bore in a drawing process in which the substrate tube is drawn from a melt, or in which a mother tube is elongated to form the substrate tube. Alternatively or in addition, and equally preferred, these measures are generated “in situ” during vitrification.

A suitable measure for realizing suspended vitrification is the formation of a holding edge on the substrate tube, which serves to ensure that the composite (1; 9) is vitrified while at least temporarily hanging vertically (and not exclusively standing). Due to the at least temporarily hanging holder, in addition to the effect of the thermally stable substrate tube 1 explained above, compression of the soot body 9 is counteracted during vitrification, so that it retains its desired geometry, and scrap is avoided.

For hanging the composite (1; 9), for example, the substrate tube section 1g can be shaped into a holding edge during vitrification of the soot body 9. Suitable methods for producing the holding edge “in situ” are explained in more detail below with reference to FIGS. 6 through 10.

FIG. 6 schematically shows a first method and a device for producing the hanger “in situ.” The composite (1; 9) consisting of the substrate tube 1 and soot body 9 is introduced into the vitrification furnace 40 and borne by means of a support rod 45 and cladding tube 47 on the platform 46 with a vertically-oriented soot body longitudinal axis 1e. An annular spacer 61 is placed on the upper end face 47a of the cladding tube 47, and a cone body 62 in the form of an inverted cup is placed on the upper end face of the substrate tube 9. The spacer 61 and the cone body 62 consist of graphite. The cone body 62 has an inner cone 62a which merges into a flat support surface 62b in which there is a through-opening 62c. In the initial state, the inner cone 62 rests on the outside of the upper substrate tube section 1g. The support rod 45 extends through the through-opening 62c and through the annular spacer 61.

The upper substrate tube section 1g is shaped into a hanger during the vitrification method. The shaping method is shown schematically in FIG. 7. By means of the support rod 45, the upper substrate tube section 1g is moved far enough into the heating element 43 heated to vitrification temperature that it softens. Due to its weight, the cone body 62 presses the soft upper substrate tube section 1g inwards in the direction of the substrate tube longitudinal axis 1e. The substrate tube section 1g rests against the inner cone 62a and is thereby shaped into an outer cone. The shaping method is completed as soon as the spacer 61 comes into contact with the support surface 62b of the cone body 62.

During further vitrification, the composite body (1; 9) is heated in zones, starting with its upper end. The composite (1; 9) successively collapses onto the graphite cladding tube 47 and also shrinks in length. The sintering shrinkage forces are strong enough that the length of the substrate tube 1 is also shortened. However, the reduction in length is small.

In a first vitrification phase, the composite (1; 9) stands on the platform 46. FIG. 8 schematically shows a second vitrification phase. During this, the former substrate tube section 1g, which has been shaped into an outer cone, comes out of the heating region of the heating element 43, cools down in the process, and solidifies. It rests with its inside on the top side of the cladding tube 47a and then acts as a hanger 63 for the composite (1; 9). As a result of the shrinkage in length, it lifts off from the platform 46 to form a narrow gap 48, which then enables further “suspended vitrification.” This counteracts the collapse of the soot body 9, wherein the substrate tube 47 additionally stabilizes the shape of the resulting tubular quartz glass composite body due to its higher viscosity.

FIG. 9 schematically shows a second method and a device for producing the hanger in situ, i.e., in one operation with the vitrification of the composite (1; 9) consisting of substrate tube 1 and soot body 9. This is introduced into the vitrification furnace 40 and borne by means of a support rod 45 and cladding tube 47 on the platform 46 with a vertically-oriented soot tube longitudinal axis 1e. On the upper end face 47a of the cladding tube 47, a circular ring 91 is placed which is composed of two or more separate circular sector plates 91a, 91b, which adjoin a circular ring center opening 91b and which are movably mounted in the radial direction. A cone body 92 of graphite projects from above into the central opening 91b and has a cone-shaped shaft 92a and a cone head 92b with a flat underside. The circular ring 91 and cone body 92 consist of graphite. The outer diameter of the circular ring 91 corresponds approximately to the inner diameter of the substrate tube 1; it rests on the inner wall of the upper substrate tube section 1g. The diameter profile of the cone shaft 92a is designed so that, in the initial state, it is approximately halfway immersed in the center opening 91b.

As the composite body (1; 9) is further vitrified, the bulge 93 reaches the region above the heating element 43, cools down in the process, and solidifies. The composite body (1, 9) is heated in zones starting with its upper end, as described above with regard to the first method. In a first vitrification phase, the composite (1; 9) stands on the platform 46 and, during the second vitrification phase, the bulge 93 serves as a holder for the “suspended vitrification.” The circular sector plates 91a protrude from the inside into the bulge 93 and are fixed therein in the vertical direction together with the substrate tube 1.

The length and inner diameter of the quartz glass composite body obtained afterwards are predetermined by the substrate tube 1. The former soot body forms a layer of transparent synthetic quartz glass with a layer thickness of around 41 mm. After removing the quartz glass material from the substrate tube 1 and grinding and smoothing the outer wall, a hollow quartz glass cylinder with an outer diameter of 360 mm and an inner diameter of 290 mm is obtained. Etching rings can be cut from this for single-wafer plasma etching chambers and pressure vessels for use in chemical process engineering.

To produce the etching ring or the pressure vessel, a composite body with an outer wall region with an inner diameter that is at least 1 mm smaller than the target inner diameter is preferably used. The target inner diameter can be adjusted by mechanical or chemical processing of the composite body inner bore.

A further exemplary embodiment for realizing a holding edge for the suspended vitrification of the composite body (21, 9) is explained below with reference to FIGS. 2 and 3 and FIGS. 11 through 13.

### Soot Deposition Process

The soot separation method is carried out as explained above with reference to FIG. 1. FIG. 11 shows the substrate tube 21 used in this case, in a longitudinal section. The previously created constriction 26 is provided in the end region 21a. As can be seen from FIG. 2, the soot body 9 is produced in such a way that it completely covers the constriction 26. However, this measure is not absolutely necessary; the constriction can also lie completely outside the soot body 9.

The deposition method is ended as soon as the soot body 9 has reached a predetermined outside diameter: At a soot density of 30% (based upon the density of quartz glass) and a target outside diameter of the quartz glass composite body of 362 mm, the soot body outside diameter is approximately 520 mm.

The composite (21; 9) present after the soot separation method is subjected to a dehydration treatment in a chlorine-containing atmosphere at a temperature of 1,200° C. By vitrifying the dried SiO₂ soot body obtained afterwards under vacuum, a synthetic quartz glass with the following properties is obtained:
Hydroxyl group content: <0.2 ppm by weight
Chlorine content: about 1,000 ppm by weight
Viscosity at 1,350° C.: 10.64 Ig (dPa·s)

The composite (21; 9) is then vitrified under vacuum in the zone sintering furnace 40. FIG. 12 shows the composite (21; 9) used in the zone sintering furnace 40. During vitrification, the heating element 43 is heated to a vitrification temperature of approximately 1,400° C., and the support rod 45 is continuously pulled upwards so that the soot body 9 is vitrified from top to bottom. The composite (21; 9) shrinks onto the graphite cladding tube 47 so that its outer diameter defines a lower limit for the inner diameter of the vitrified quartz glass composite body. Since the substrate tube 21 consists of a quartz glass which has a higher viscosity at the vitrification temperature than the quartz glass of the soot body 9, it does not deform or deforms slightly, and causes the soot body 9 to be stabilized during vitrification. In particular, the risk is counteracted of the soot body 9 compressing during vitrification and circumferential folds forming, or the inside diameter widening.

In the shown method stage, the vitrification process has already progressed, and a certain shrinkage of the soot body 9 has already taken place. This means that the transition from the initial vitrification phase with the standing composite (21; 9) to “suspended vitrification” has already been completed. Due to the shrinkage of the soot body 9, the length of the substrate tube 21 has also shortened a little, and a piece has already lifted off the platform 46 while forming the gap 98.

In an alternative procedure, the composite (21; 9) is kept suspended in the zone sintering furnace from the start, in that the constriction 26, which already exists before the soot separation method, rests on the upper edge of the graphite cladding tube 47.

After cooling, a composite body 100 (FIG. 13) is obtained from the substrate tube 21 and a glass layer 9a with a thickness of approximately 41 mm, which has been obtained by vitrifying the soot body 9.

In a comparative test, a substrate tube of synthetic quartz glass with the same dimensions as the substrate tube 21 was used, as specified in Table 1. The viscosity of this quartz glass is higher than the viscosity of the quartz glass obtained by vitrifying the soot body 9. More specifically, the decadal logarithm of the viscosity of this quartz glass at a measuring temperature of 1,350° C. is 0.13 lg (dPa*s) higher than the decadal logarithm of the viscosity of the quartz glass obtained by vitrifying the soot body 9.

However, it turns out that this difference in viscosity is too small to lend the large-volume and heavy substrate tube sufficient stability when sintering the composite body.

FIG. 13 shows a cross-section of the composite body 100 obtained after vitrification in a view along the line A′-A″ drawn in FIG. 2. The substrate tube 1 with the through-holes 1f, the diameter constriction 26, and the layer 9a of synthetic quartz glass obtained after vitrification can be seen.

After removing the quartz glass material from the substrate tube 21 and grinding and smoothing the outer wall, a hollow quartz glass cylinder with an outer diameter of 360 mm and an inner diameter of 290 mm is obtained. Etching rings with the corresponding inner and outer diameter values—or with larger inner and smaller outer diameter values—can be sawn therefrom for use in holding semiconductor wafers in single-wafer plasma etching chambers or pressure vessels for industrial use.

1. A method for producing a tubular quartz glass composite body in an outside deposition method comprising the following method steps:
(a) Providing a substrate tube which has a continuous through-opening running coaxially with a substrate tube longitudinal axis, a substrate tube outer diameter, a substrate tube inner diameter, a substrate tube wall thickness, a substrate tube outer lateral surface, and a substrate tube inner lateral surface,
(b) Rotating the substrate tube about an axis of rotation running coaxially with or parallel to the substrate tube longitudinal axis,
(c) Depositing SiO₂ particles on the outer lateral surface of the substrate tube by means of at least one deposition burner to form a composite (1/9; 21/9) consisting of the substrate tube and a SiO₂ soot body,
(d) Sintering the composite (1/9; 21/9) by heating at a sintering temperature to form the tubular quartz glass composite body (100),
wherein a substrate tube is provided which consists at least partially of quartz glass of a first quartz glass quality, and that the soot body consists of quartz glass of a second quartz glass quality, wherein the first quartz glass quality has a material-specific viscosity at the sintering temperature that is higher than the material-specific viscosity of the second quartz glass quality.

2. The method according to claim 1, wherein, at a measuring temperature of 1,350° C., the decadal logarithm of the viscosity of the first quartz glass quality is at least 0.25 lg(dPa*s), preferably at least 0.4 lg(dPa*s), particularly preferably at least 0.6 lg(dPa*s) higher than that of the quartz glass of the second quartz glass quality.

3. The method according to claim 1, wherein the quartz glass of the first quartz glass quality has an aluminum oxide content that is at least 5 ppm by weight, preferably at least 10 ppm by weight, higher than the aluminum oxide content in the quartz glass of the second quartz glass quality.

4. The method according to claim 1, wherein the quartz glass of the first quartz glass quality has a hydroxyl group content of less than 30 ppm by weight, preferably a hydroxyl group content of less than 20 ppm by weight.

5. The method according to claim 1, wherein the quartz glass of the first quartz glass quality is melted from a naturally occurring raw material.

6. The method according to claim 1, wherein the substrate tube has a wall thickness in a range of 1.5 mm to 10 mm, preferably in a range of 4 to 8 mm.

7. The method according to claim 1, wherein the soot body is essentially cylindrical and has a wall thickness which, after sintering the composite body, results in a glass layer which has a layer thickness in a range of 25 mm to 100 mm, preferably in a range of 30 mm to 60 mm.

8. A tubular composite body of quartz glass with a length of at least 1,000 mm, a tube wall, and with an inner diameter of at least 250 mm, wherein the raw wall comprises an inner wall region and an outer wall region, wherein the inner wall region at least partially consists of quartz glass of a first quartz glass quality, and the outer wall region consists of quartz glass of a second quartz glass quality, wherein, at a measuring temperature of 1,350° C., the viscosity of the first quartz glass quality is higher than the viscosity of the second quartz glass quality.

9. The composite body according to claim 8, wherein, at a measuring temperature of 1,350° C., the decadal logarithm of the viscosity of the first quartz glass quality is at least 0.25 lg(dPa*s), preferably at least 0.4 lg(dPa*s), particularly preferably at least 0.6 lg(dPa*s) higher than that of the quartz glass of the second quartz glass quality.

10. The composite body according to claim 8, wherein the quartz glass of the first quartz glass quality has an aluminum oxide content which is at least 5 ppm by weight, preferably at least 10 ppm by weight, higher than the aluminum oxide content in the quartz glass of the second quartz glass quality.

11. The composite body according to claim 8, wherein the quartz glass of the first quartz glass quality is melted from a naturally occurring raw material.

12. The composite body according to claim 8, wherein the inner wall region consisting of the first quality quartz glass has a wall thickness in a range of 1.5 mm to 10 mm, preferably in a range of 4 to 8 mm.

13. The composite body according to claim 8, wherein the outer wall region has a wall thickness in a range of 25 mm to 100 mm, preferably in a range of 30 mm to 60 mm.

14. A use of the tubular composite body according to claim 9 for producing etching rings for semiconductor production or a pressure vessel, wherein a quartz glass hollow cylinder is produced by removing the inner wall region, and this is processed into the etching rings or the pressure vessel.

15. The use according to claim 14, wherein the etching ring or the pressure vessel has a predetermined target inner diameter, and that, to produce the etching ring or the pressure vessel, a composite body is used with an outer wall region with an inner diameter that is at least 1 mm smaller than the target inside diameter.
